(19) United States
(12) Patent Application Publication
(10) Pub. No.: US 2026/0314195 A1
(43) Pub. Date: Oct. 8, 2026

(54) Display Apparatus And Electronic Apparatus

(71) Applicant: Samsung Display Co., Ltd., Yongin-si (KR)

(72) Inventors: Heeju Woo, Yongin-si (KR); Kiyong Kim, Yongin-si (KR); Cholong Won, Yongin-si (KR)

(73) Assignee: Samsung Display Co., Ltd., Yongin-si (KR)

(21) Appl. No.: 19/411,667

(22) Filed: Dec. 8, 2025

(30) Foreign Application Priority Data
Apr. 3, 2025 (KR) 10-2025-0043610

(51) Int. Cl. H10K 59/131

(52) U.S. Cl. CPC H10K 59/131

(57) ABSTRACT

A display apparatus with improved reliability includes a substrate including a display area and a peripheral area outside the display area, a display element disposed on the display area, and a pad disposed on the peripheral area. The pad includes a first conductive layer disposed on the peripheral area, a second conductive layer disposed on the first conductive layer, a convex portion interposed between the first conductive layer and the second conductive layer, and a protrusion interposed between the first conductive layer and the convex portion. At least a portion of the protrusion overlaps the convex portion in a thickness direction of the pad.

### CROSS-REFERENCE TO RELATED APPLICATION

This application claims priority under 35 U.S.C. §119 to Korean Patent Application No. 10-2025-0043610, filed on Apr. 3, 2025, in the Korean Intellectual Property Office, the disclosure of which is incorporated by reference herein in its entirety.

### TECHNICAL FIELD

One or more embodiments relate to display apparatuses and electronic apparatuses including the same, and more particularly, to a display apparatus and an electronic apparatus having improved reliability.

### BACKGROUND

Display apparatuses receive information about an image and display the image. These display apparatuses may include a display panel for displaying the image and an electronic chip package or printed circuit board for providing information about the image. To receive the information about the image, the display panel includes, at an edge thereof, pads electrically connected to display elements. The pads are also electrically connected to bumps of the electronic chip package. To this end, the pads of the display panel are bonded with the bumps of the electronic chip package corresponding thereto by using an adhesive tape (or the like).

However, a problem exists in that an adhesive strength between pads of a display panel and bumps of an electronic chip package is low, and/or a contact resistance between the pads of the display panel and the bumps of the electronic chip package is high.

### BRIEF SUMMARY

One or more embodiments include a display apparatus having improved reliability, and an electronic apparatus including the display apparatus with such improved reliability. However, aspects of embodiments according to the present disclosure are not limited thereto, and the above mentioned characteristics do not limit the scope of embodiments according to the present disclosure.

Additional aspects of the disclosure will be set forth in the portion of the description which follows and, in part, will be apparent from the description, or may be learned by practice of the presented embodiments of the disclosure.

According to one or more embodiments, a display apparatus includes a substrate including a display area and a peripheral area outside the display area, a display element disposed on the display area, and a pad disposed on the peripheral area. The pad includes a first conductive layer disposed on the peripheral area, a second conductive layer disposed on the first conductive layer, a convex portion interposed between the first conductive layer and the second conductive layer, and a protrusion interposed between the first conductive layer and the convex portion, at least a portion of the protrusion overlapping the convex portion in a thickness direction of the pad, i.e., in a direction of a thickness of the display apparatus. Further references to overlapping elements may also be understood to be overlapping in the thickness direction.

A portion of the convex portion may be in direct contact with the first conductive layer, and another portion of the convex portion may be in direct contact with the protrusion.

The convex portion may include a first convex portion and a second convex portion which are arranged apart from each other along a first direction.

The protrusion may include a first protrusion and a second protrusion which are arranged apart from each other along a first direction. The first protrusion may be interposed between the first conductive layer and the first convex portion, and at least a portion of the first protrusion overlaps the first convex portion. The second protrusion may be interposed between the first conductive layer and the second convex portion, and at least a portion of the second protrusion may overlap the second convex portion.

The first protrusion may include a 1-1 protrusion and a 1-2 protrusion, i.e., a first sub-protrusion and a second sub-protrusion, respectively, which are arranged apart from each other along a second direction intersecting the first direction. Each of the 1-1 protrusion and the 1-2 protrusion may at least partially overlap the first convex portion.

In a plan view, the 1-1 protrusion may extend along one side of the first convex portion. In a plan view, the 1-2 protrusion may extend along a side opposite to the one side of the first convex portion.

The second protrusion may include a 2-1 protrusion and a 2-2 protrusion, i.e., a first sub-protrusion and a second sub-protrusion, respectively, which are arranged apart from each other along the second direction Each of the 2-1 protrusion and the 2-2 protrusion may at least partially overlap the second convex portion.

In a plan view of the display apparatus, i.e., a plane perpendicular to the thickness direction of the pad, the 2-1 protrusion may extend along one side of the second convex portion and the 2-2 protrusion may extend along a side opposite to the one side of the second convex portion.

The 1-1 protrusion and the 2-1 protrusion may be integrally provided, and separately, the 1-2 protrusion and the 2-2 protrusion may be integrally provided.

The first protrusion may include a 1-1 protrusion and a 1-2 protrusion which are arranged apart from each other along the first direction, and each of the 1-1 protrusion and the 1-2 protrusion may at least partially overlap the first convex portion.

The second protrusion may include a 2-1 protrusion and a 2-2 protrusion which are arranged apart from each other along the first direction, and each of the 2-1 protrusion and the 2-2 protrusion may at least partially overlap the second convex portion.

The second conductive layer may cover the convex portion and the first conductive layer.

A portion of the second conductive layer may be in direct contact with the convex portion, and another portion of the second conductive layer may be in direct contact with the first conductive layer.

The convex portion may include a first portion that overlaps the protrusion and a second portion that does not overlap the protrusion. Further, a length between an upper surface of the first portion and an upper surface of the first conductive layer may be greater than a length between an upper surface of the second portion and the upper surface of the first conductive layer.

The display apparatus may further include a lower conductive layer disposed below the first conductive layer and electrically connected to the first conductive layer.

According to one or more embodiments, an electronic apparatus includes a processor, and a display apparatus controlled by the processor. The display apparatus includes a substrate including a display area and a peripheral area outside the display area, a display element disposed on the display area, and a pad disposed on the peripheral area. The pad includes a first conductive layer disposed on the peripheral area, a second conductive layer disposed on the first conductive layer, a convex portion interposed between the first conductive layer and the second conductive layer, and a protrusion interposed between the first conductive layer and the convex portion, at least a portion of the protrusion overlapping the convex portion.

A portion of the convex portion may be in direct contact with the first conductive layer, and another portion of the convex portion may be in direct contact with the protrusion.

The convex portion may include a first convex portion and a second convex portion which are arranged apart from each other along a first direction. The protrusion may include a first protrusion and a second protrusion which are arranged apart from each other along a first direction. The first protrusion may be interposed between the first conductive layer and the first convex portion, and at least a portion of the first protrusion may overlap the first convex portion. The second protrusion may be interposed between the first conductive layer and the second convex portion. At least a portion of the second protrusion may overlap the second convex portion.

The convex portion may include a first portion that overlaps the protrusion and a second portion that does not overlap the protrusion. Further, a length between an upper surface of the first portion and an upper surface of the first conductive layer may be greater than a length between an upper surface of the second portion and the upper surface of the first conductive layer.

The display apparatus may further include a lower conductive layer disposed below the first conductive layer and electrically connected to the first conductive layer.

These and/or other aspects will become apparent and more readily appreciated from the following description of the embodiments, the claims, and the accompanying drawings.

### BRIEF DESCRIPTION OF THE DRAWINGS

The above and other aspects, features, and advantages of certain embodiments of the present disclosure will be more apparent from the following description in conjunction with the accompanying drawings, in which:

FIG. 1A is a schematic block diagram of an electronic apparatus according to an embodiment;

FIG. 1B is a schematic diagram of electronic apparatuses according to various embodiments;

FIG. 2 is a schematic plan view of a display apparatus according to an embodiment;

FIG. 3 is an equivalent circuit diagram of one pixel circuit included in the display apparatus of FIG. 2;

FIG. 4 is a schematic cross-sectional view of the display apparatus of FIG. 2 taken along line I-I';

FIG. 5 is a schematic magnified plan view of a portion A of the display apparatus of FIG. 2;

FIG. 6 is a schematic cross-sectional view of the display apparatus of FIG. 5 taken along line II-II';

FIG. 7 is a schematic cross-sectional view of the display apparatus of FIG. 5 taken along line III-III';

FIG. 8 is a schematic magnified cross-sectional view of a portion B of the display apparatus of FIG. 6;

FIG. 9 is a schematic cross-sectional view of a display apparatus according to an embodiment;

FIG. 10 is a schematic plan view of a display apparatus according to an embodiment; and

FIG. 11 is a schematic plan view of a display apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below by referring to the figures, to explain aspects of the present description. As used herein, the term "and/or" includes any and all combinations of one or more of the associated listed items. For example, "A and/or B" represents A or B, or A and B. Throughout the disclosure, the expression "at least one of a, b or c" indicates only a, only b, only c, both a and b, both a and c, both b and c, all of a, b, and c, or variations thereof.

As the disclosure allows for various changes to the described embodiments and numerous embodiments in their own right, particular embodiments will be illustrated in the drawings and described in detail in the written description. Hereinafter, effects and features of the disclosure and a method for accomplishing them will be described more fully with reference to the accompanying drawings, in which embodiments of the disclosure are shown. The disclosure may, however, be

embodied in many different forms and should not be construed as limited to the embodiments set forth herein.

It will be understood that although the terms "first," "second," etc. may be used herein to describe various components, these components should not be limited by these terms. These components are only used to distinguish one component from another.

As used herein, the singular forms "a," "an," and "the" are intended to include the plural forms as well, unless the context clearly indicates otherwise.

It will be further understood that the terms "comprises" and/or "comprising" used herein specify the presence of stated features or components, but do not preclude the presence or addition of one or more other features or components.

It will be understood that, unless otherwise specified, when an element such as a layer, film, region or substrate is referred to as being “on” another element, it can be “directly” on the other element or intervening elements may also be present.

When a layer, region, or component is referred to as being "connected" or "coupled" to another layer, region, or component, it can be directly connected or coupled to the other layer, region, or/and component or intervening layers, regions, or components may be present. For example, when a layer, region, or component is referred to as being "electrically connected" or "electrically coupled" to another layer, region, or component, it can be directly electrically connected or coupled to the other layer, region, and/or component or intervening layers, regions, or components may be present.

In the following examples, the x-axis, the y-axis and the z-axis are not limited to three axes of the cartesian coordinate system, and may be interpreted in a broader sense. For example, the x-axis, the y-axis, and the z-axis may be perpendicular to one another, or may represent respective directions that are not perpendicular to one another.

When a certain embodiment may be implemented differently, a specific process order for that implementation may be performed differently from the described order. For example, two consecutively described processes may be performed substantially at the same time or performed in an order opposite to the described order.

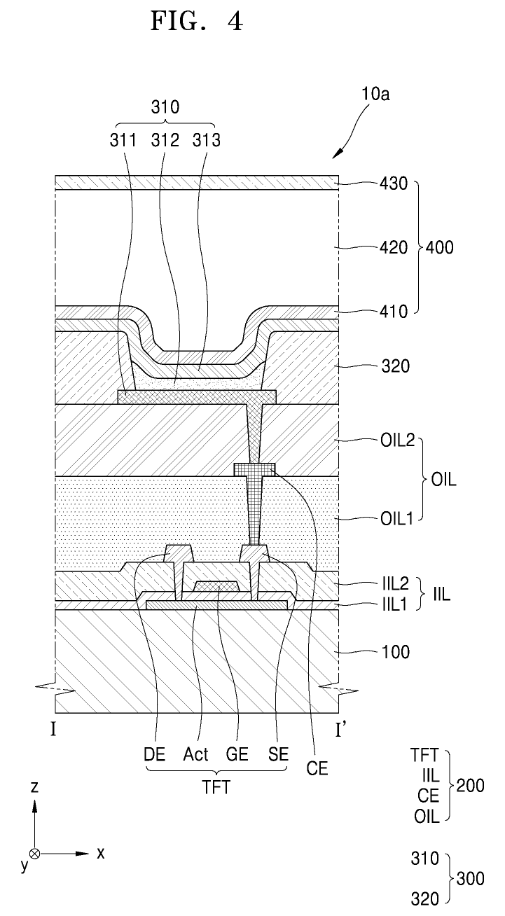

The expression "in a plan view" as used herein refers to when an object portion is viewed from the top, e.g., the top of the display apparatus 10. In other words, the expression "in a plan view" used herein may refer to "when viewed in a direction perpendicular to a large surface area surface of a substrate 100". The large surface area of the substrate 100 in the embodiment of FIGS. 4-6 may be in the xy plane (plane coincident with x-axis and y-axis).

One or more embodiments of the disclosure will be described below in more detail with reference to the accompanying drawings. Those components that are the same as or are in correspondence with each other are rendered the same reference numeral regardless of the figure number, and redundant explanations are omitted. In the drawings, the thicknesses of layers and regions are exaggerated or reduced for convenience of explanation. For example, since sizes and thicknesses of components in the drawings are arbitrarily illustrated for convenience of explanation, embodiments are not limited thereto.

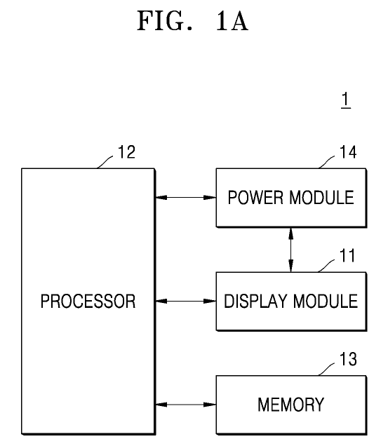

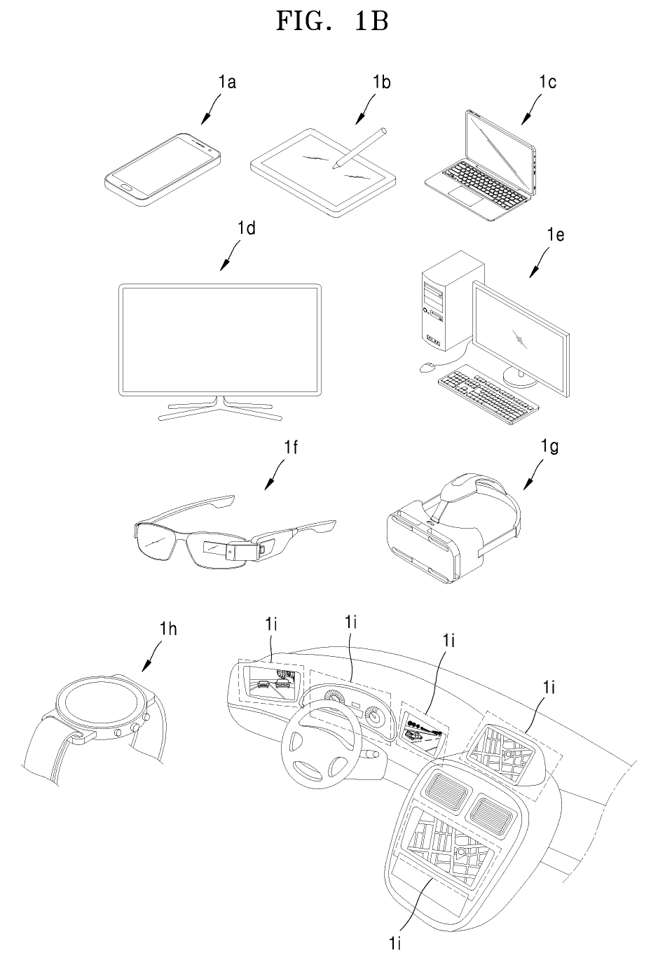

FIG. 1A is a schematic block diagram of an electronic apparatus 1 according to an embodiment. The electronic apparatus 1 according to an embodiment may further include, for example, a module having other additional functions in addition to a display module 11. For example, as shown in FIG. 1A, the electronic apparatus 1 according to the depicted embodiment may include the display module 11, a processor 12, a memory 13, and a power module 14.

The processor 12 may control the components of the electronic apparatus 1. The processor 12 may include at least one of a central processing unit (CPU), an application processor (AP), a graphics processing unit (GPU), a communication processor (CP), an image signal processor (ISP), or a controller.

The memory 13 may store data information necessary for an operation of the processor 12 or the display module 11. When the processor 12 executes an application stored in the memory 13, an input control signal and/or a data signal for an image may be transmitted to the display module 11, and the display module 11 may process the received signal and output image information.

The power module 14 may include a power supply module, such as a power adapter or a battery device, and a power conversion module that converts power supplied by the power supply module to generate power necessary for an operation of the electronic apparatus 1.

FIG. 1B is a schematic diagram of electronic apparatuses 1 according to various embodiments. Referring to FIG. 1B, the electronic apparatuses 1 that each include the display module 11 may include not only image display electronic apparatuses (such as, a smartphone 1a, a tablet PC 1b, a laptop 1c, a TV 1d, and a desk monitor 1e), but also wearable electronic apparatuses including display modules (such as, smart glasses 1f, a head mounted display 1g, and a smart watch 1h), and vehicle electronic apparatuses 1i that include display modules (such as, a center information display (CID) disposed on an instrument panel, center fascia, or dashboard of automobiles, and a room mirror display).

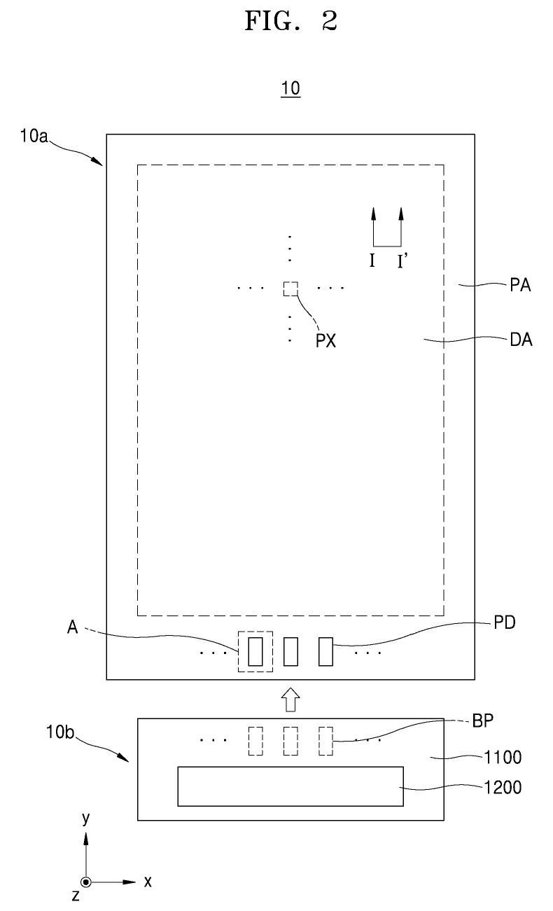

The display module 11 may include a display apparatus 10 as shown in FIG. 2. The display apparatus 10 may be applied to and incorporated into various electronic apparatuses 1. In other words, the electronic apparatus 1 may include the display apparatus 10, and may further include a module or device having other additional functions in addition to the display apparatus 10. For example, the electronic apparatus 1 may include the display apparatus 10, the processor 12, the memory 13, and the power module 14, and the display apparatus 10 may be controlled by the processor 12. The display apparatus 10 will now be focused on and described.

FIG. 2 is a schematic plan view of the display apparatus 10 according to an embodiment. As shown in FIG. 2, the display apparatus 10 may include a display panel 10a and an electronic chip package 10b. The display panel 10a may display an image, and the electronic chip package 10b may provide information about the image to the display panel 10a.

The display panel 10a may include a display area DA in which a plurality of pixels PX are arranged, and a peripheral area PA located outside the display area DA. In some examples, the peripheral area PA may surround the entire display area DA.

Each of the pixels PX of the display panel 10a is an area capable of emitting light of a certain color, and the display panel 10a may provide an image by using light emitted by the pixels PX. For example, each of the pixels PX may emit red light, green light, or blue light. One pixel PX may correspond to one display element, and the one display element may emit red light, green light, or blue light. In this disclosure, when one pixel corresponds to one display element or one display element corresponds to one pixel, it means that one pixel is an emission area of one display element.

The display area DA may have the shape of a polygon such as a quadrangle, as shown in FIG. 2. In examples, the display area DA may have a rectangular shape in which a horizontal length is less than a vertical length, a rectangular shape in which a horizontal length is greater than a vertical length, or a square shape. Alternatively, the display area DA may have any one of various shapes such as an oval shape or a circular shape.

The peripheral area PA may be a non-display area in which no display pixels PX are disposed. A driver or the like for providing an electrical signal or power to the display pixels PX may be arranged in the peripheral area PA. In addition, as illustrated in FIG. 2, a plurality of pads PD, which are areas to which the electronic chip package 10b, a printed circuit board, or the like may be electrically connected, may be arranged in the peripheral area PA.

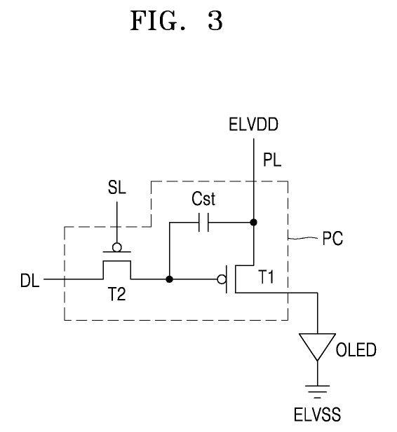

Each of the pads PD may be apart, i.e. spaced apart from each other in the peripheral area PA, and may be electrically connected to a plurality of connection wires (not shown) arranged in the peripheral area PA. The connection wires may electrically connect signal lines arranged in the display area DA, for example, data lines DL (see FIG. 3) (or scan lines SL (see FIG. 3)), to the pads PD. Each pad PD may be electrically connected to or may be in direct contact with a respective bump BP from among a plurality of bumps BP arranged on a lower surface of the electronic chip package 10b. That is, the pads PD may exchange electrical signals with the bumps BP. Accordingly, the electronic chip package 10b may be electrically connected to the display panel 10a.

The electronic chip package 10b may include an electronic chip 1200 and a body 1100 on which the electronic chip 1200 is mounted. The electronic chip 1200 may include, for example, an integrated circuit (IC) chip and may be a data driver that generates data signals that are to be applied to data lines within the display area DA. The body 1100 may be a flexible film. That is, the electronic chip package 10b may have a chip on film (COF) structure. In some examples, the electronic chip package 10b may include bumps BP arranged under the body 1100, and each bump BP from among the plurality of bumps BP of the electronic chip package 10b may be respectively arranged on a pad PD from among a plurality of pads PD. These bumps BP may be electrically connected to the electronic chip 1200.

However, the disclosure is not limited thereto. For example, the electronic chip package 10b of the display apparatus 10 may not include the body 1100. That is, the electronic chip package 10b may have a chip on panel (COP) structure. When the electronic chip package 10b does not include the body 1100, the bumps BP may be disposed under the electronic chip 1200. For convenience of explanation, the electronic chip package 10b will now be described as including the electronic chip 1200 and the body 1100 on which the electronic chip 1200 is mounted.

The plurality of pads PD may be electrically connected to the plurality of bumps BP of the corresponding electronic chip package 10b, and thus the display panel 10a may be electrically connected to the electronic chip package 10b, etc. For example, the plurality of pads PD may be in direct contact with the plurality of bumps BP of the electronic chip package 10b disposed on

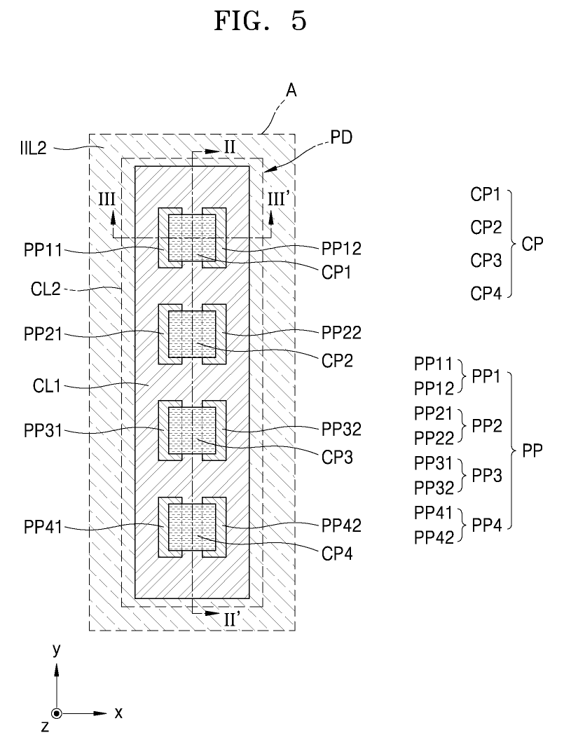

the plurality of pads PD so that the plurality of pads PD may be electrically connected to the plurality of bumps BP of the electronic chip package 10b. For convenience of illustration, FIG. 2 illustrates that the plurality of pads PD of the display panel 10a as spaced apart from the plurality of bumps BP of the electronic chip package 10b. As described above, the bumps BP of the electronic chip package 10b may be arranged on the plurality of pads PD. However, for convenience of illustration, illustration of the bumps BP of the electronic chip package 10b is omitted in FIGS. 5 through 11.

FIG. 3 is an equivalent circuit diagram of one pixel circuit PC included in the display apparatus 10 of FIG. 2. The pixel circuit PC may be electrically connected to a display element, and one display element may correspond to one pixel. In FIG. 3, an organic light-emitting diode OLED is shown as a display element. According to an embodiment, the display element may emit red light, green light, or blue light.

The pixel circuit PC may include a first transistor T1, a second transistor T2, and a storage capacitor Cst. The second transistor T2, which is a switching transistor, may be connected to a scan line SL and a data line DL, and may be turned on by a switching signal received from the scan line SL to transmit, to the first transistor T1, a data signal received from the data line DL. The storage capacitor Cst may have one end electrically connected to the second transistor T2 and the other end electrically connected to a driving voltage line PL, and may store a voltage corresponding to the difference between a voltage received from the second transistor T2 and a driving power supply voltage ELVDD supplied to the driving voltage line PL.

The first transistor T1, which is a driving transistor, may be connected to the driving voltage line PL and the storage capacitor Cst, and may be configured to control the magnitude of a driving current flowing from the driving voltage line PL to the organic light-emitting diode OLED, in accordance with a voltage value stored in the storage capacitor Cst. The organic light-emitting diode OLED may emit light having a certain brightness due to the driving current. An opposite electrode of the organic light-emitting diode OLED may receive an electrode power supply voltage ELVSS.

Although FIG. 3 illustrates that the pixel circuit PC includes two transistors and one storage capacitor, the disclosure is not limited thereto. For example, the number of transistors or the number of storage capacitors may vary according to a design of the pixel circuit PC.

FIG. 4 is a schematic cross-sectional view of the display apparatus 10 of FIG. 2 taken along line I-I'. As will be recognized by those skilled in the art, the display apparatus 10 may further include various components other than the components shown in FIG. 4.

As illustrated in FIG. 4, the display panel 10a of the display apparatus 10 may include a substrate 100, a pixel circuit layer 200, a display element layer 300, and an encapsulation layer 400. Because the display panel 10a includes the substrate 100, it may be considered that the substrate 100 has a portion in the display area DA and another portion in the peripheral area PA. For convenience of explanation, the substrate 100 will now be described as representative of the substrate in the display area DA and the peripheral area PA.

The substrate 100 may include glass, a metal, or a polymer resin. Further, the substrate 100 has flexible or bendable characteristics. In this case, the substrate 100 may include polymer resin such as polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers each including a polymer resin and a barrier layer including an inorganic material (e.g., silicon oxide (SiO_{X}), silicon nitride (SiN_{X}), silicon oxynitride (SiO_{X}N_{Y}), or the like) that is located between the two layers. In this way, various modifications may be made.

The pixel circuit layer 200 may be disposed on the substrate 100. The pixel circuit layer 200 may include a transistor TFT, an inorganic insulating layer IIL, a connection electrode CE, and an organic insulating layer OIL. The transistor TFT may include a semiconductor layer Act, a gate electrode GE, a source electrode SE, and a drain electrode DE. The inorganic insulating layer IIL may include a first inorganic insulating layer IIL1 and a second inorganic insulating layer IIL2. The organic insulating layer OIL may include a first organic insulating layer OIL1 and a second organic insulating layer OIL2. For convenience of illustration, one transistor TFT is shown in FIG. 4, and the transistor TFT may correspond to the above-described first transistor T1 of FIG. 3.

The semiconductor layer Act may be arranged on the substrate 100. The semiconductor layer Act may include polysilicon. Alternatively, the semiconductor layer Act may include amorphous silicon, an oxide semiconductor, or an organic semiconductor. According to an embodiment, the semiconductor layer Act may include a channel region, and a source region and a drain region respectively arranged on both sides of the channel region.

The first inorganic insulating layer IIL1 may be disposed on the semiconductor layer Act. Specifically, the first inorganic insulating layer IIL1 may be disposed on the semiconductor layer Act and the substrate 100. The first inorganic insulating layer IIL1 may include an inorganic insulating material such as silicon oxide (SiO_{X}), silicon nitride (SiN_{X}), or silicon oxynitride (SiO_{X}N_{Y}). For example, the first inorganic insulating layer IIL1 may have a single-layer or multi-layer structure including the above-mentioned material. As such, an insulating layer including an inorganic insulating material may be formed via a method such as chemical vapor deposition (CVD). This may be equally applied to embodiments to be described below and modifications thereof.

In FIG. 4, the first inorganic insulating layer IIL1 is illustrated as having a shape corresponding to the entire surface of the display area DA and having a structure in which contact holes are formed in a preset (i.e., predetermined) portion of the first inorganic insulating layer IIL1. However, the disclosure is not limited thereto. For example, the first inorganic insulating layer IIL1 may be patterned in the same shape as the gate electrode GE.

The gate electrode GE may be disposed on the first inorganic insulating layer IIL1. That is, the first inorganic insulating layer IIL1 may be disposed between the semiconductor layer Act and the gate electrode GE to provide insulation between the semiconductor layer Act and the gate electrode GE. The gate electrode GE may overlap the channel region of the semiconductor layer Act. The gate electrode GE may include a low resistance metal material. According to an embodiment, the gate electrode GE may include a conductive material including, for example, molybdenum (Mo), aluminum (Al), copper (Cu), or titanium (Ti), and may have a single-layer or multi-layer structure including the aforementioned conductive materials. In some examples, the conductive material may include any combination of the above-mentioned metals.

The second inorganic insulating layer IIL2 may be disposed on the gate electrode GE. Specifically, the second inorganic insulating layer IIL2 may be disposed on the gate electrode GE and the first inorganic insulating layer IIL1 The second inorganic insulating layer IIL2 may include an inorganic insulating material such as silicon oxide (SiO_{X}), silicon nitride (SiN_{X}), or silicon oxynitride (SiO_{X}N_{Y}). The second inorganic insulating layer IIL2 may have a single-layer or multi-layer structure including the above-mentioned material.

The source electrode SE and the drain electrode DE may be arranged on the second inorganic insulating layer IIL2. The source electrode SE and the drain electrode DE may each be connected to the semiconductor layer Act via contact holes formed in the first inorganic insulating layer IIL1 and the second inorganic insulating layer IIL2. At least one of the source electrode SE and the drain electrode DE may include a conductive material including, for example, molybdenum (Mo), aluminum (Al), copper (Cu), or titanium (Ti), and may have a multi-layer or single-layer structure including the aforementioned conductive materials. In some examples, the conductive material may include any combination of the above-mentioned metals. According to an embodiment, at least one of the source electrode SE and the drain electrode DE may have a multi-layer structure of Ti/Al/Ti.

However, embodiments are not limited thereto. For example, the transistor TFT may include only one of the source electrode SE and the drain electrode DE, or may include neither of them. For example, one transistor TFT may be absent the drain electrode DE, another transistor TFT connected to the one transistor TFT may be absent the source electrode SE, and the semiconductor layers Act of these two transistors may be connected to each other. This connection structure may provide the same effect as when one transistor TFT includes the source electrode SE and another transistor TFT includes the drain electrode DE and the source electrode SE of the one transistor TFT is connected to the drain electrode DE of the other transistor TFT.

The first organic insulating layer OIL1 may be disposed on the source electrode SE and the drain electrode DE. Specifically, the first organic insulating layer OIL1 may be disposed on the source electrode SE, the drain electrode DE, and the second inorganic insulating layer IIL2. The first organic insulating layer OIL1 may be an organic insulating layer that covers upper portions of the source electrode SE and the drain electrode DE and has a substantially flat upper surface to serve as a planarization layer. The first organic insulating layer OIL1 may include an organic material, such as, acryl, benzocyclobutene (BCB) or hexamethyldisiloxane (HMDSO). Various modifications may be made to the first organic insulating layer OIL1. For example, the first organic insulating layer OIL1 may include a single layer or multiple layers.

The connection electrode CE may be disposed on the first organic insulating layer OIL1. The connection electrode CE may be connected to the source electrode SE or the drain electrode DE via a contact hole formed in the first organic insulating layer OIL1. Accordingly, the connection electrode CE may be connected to the semiconductor layer Act. The connection electrode CE may include a conductive material including molybdenum (Mo), aluminum (Al), copper (Cu), or titanium (Ti), and may have a single-layer or multi-layer structure including the aforementioned conductive material. According to an embodiment, the connection electrode CE may have a multi-layer structure of Ti/Al/Ti.

The second organic insulating layer OIL2 may be disposed on the connection electrode CE. Specifically, the second organic insulating layer OIL2 may be disposed on the connection electrode CE and the first organic insulating layer OIL1. The second organic insulating layer OIL2 may be an organic insulating layer that covers upper portions of the connection electrode CE and the first organic insulating layer OIL1 and has a substantially flat upper surface to serve as a planarization layer. The second organic insulating layer OIL2 may include an organic material, such as, acryl, benzocyclobutene (BCB) or hexamethyldisiloxane (HMDSO). Various modifications may be made to the second organic insulating layer OIL2. For example, the second organic insulating layer OIL2 may include a single layer or multiple layers.

The display element layer 300 may be disposed on the pixel circuit layer 200. The display element layer 300 may include a display element 310 and a pixel-defining layer 320. In other words, the display element 310 may be disposed on the display area DA of the substrate 100. The display element 310 may be electrically connected to the transistor TFT. The display element 310 may be, for example, an organic light-emitting diode having a pixel electrode 311, an opposite electrode 313, and an emission layer 312 therebetween. The display element 310 being electrically connected to the transistor TFT may be understood as the pixel electrode 311 of the organic light-emitting diode being electrically connected to the transistor TFT.

The pixel electrode 311 may be disposed on the second organic insulating layer OIL2. The pixel electrode 311 may be electrically connected to the connection electrode CE by contacting the connection electrode CE through a contact hole formed in the second organic insulating layer OIL2, and the connection electrode CE may be electrically connected to the transistor TFT by contacting one of the source electrode SE and the drain electrode DE through a contact hole formed in the first organic insulating layer OIL1. Accordingly, the pixel electrode 311 may be electrically connected to the transistor TFT. The pixel electrode 311 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound of these materials. According to another embodiment, the pixel electrode 311 may further include a film formed of ITO, IZO, ZnO, or In₂O₃ over or under the reflection layer.

The pixel-defining layer 320 may cover an edge of the pixel electrode 311. The pixel-defining layer 320 may include a pixel opening, and the pixel opening may overlap the pixel electrode 311. For example, the pixel opening may expose the central portion of the pixel electrode 311 of the display element 310, and at least a portion of the emission layer 312 of the display element 310 may be located within the pixel opening. An emission area of light emitted by the display element 310 may be defined by the pixel opening.

In such a case as illustrated in FIG. 4, the pixel-defining layer 320 may increase a distance between an edge of the pixel electrode 311 and the opposite electrode 313 over the pixel electrode 311. Accordingly, an arc or the like may be prevented from occurring on the edge of the pixel electrode 311. The pixel-defining layer 320 may include an organic insulating material, for example, polyimide or HMDSO. According to some embodiments, the pixel-defining layer 320 may include a light-blocking material.

The opposite electrode 313 may be disposed on the pixel electrode 311. The opposite electrode 313 may be provided integrally over an entire surface of the display area DA, and thus may be provided as a single electrode structure common to a plurality of organic light-emitting diodes. In other words, the opposite electrode 313 may be integrally provided over the plurality of display elements 310. Accordingly, the opposite electrode 313 may correspond to a plurality of pixel electrodes 311. The opposite electrode 313 may include a light-transmissive conductive layer formed of ITO, In₂O₃, or IZO, and may also include a semi-transmissive layer including a metal such as Al or Ag. For example, the opposite electrode 313 may be a semi-transmissive layer including Mg or Ag.

The emission layer 312 capable of emitting light may be interposed between the pixel electrode 311 and the opposite electrode 313. The emission layer 312 may emit red light, green light, or blue light. The emission layer 312 may include a high molecular or low molecular weight organic material capable of emitting light of a certain color (e.g., red, green, or blue). For example, the emission layer 312 may include a high-molecular weight material such as a polyphenylene vinylene (PPV)-based material or a polyfluorene-based material. The emission layer 312 may be formed via screen printing, inkjet printing, laser induced thermal imaging (LITI), or the like. However, the disclosure is not limited thereto.

According to an embodiment, function layers (not shown) may be disposed below and/or over the emission layer 312. The functional layers may include a hole injection layer (HIL), a hole transport layer (HTL), an electron transport layer (ETL), and/or an electron injection layer (EIL). Each of the functional layers may be integrated over the plurality of pixel electrodes 311, or may be patterned to correspond to the plurality of pixel electrodes 311.

Because the display element 310 may be easily damaged by external moisture, oxygen, or the like, the encapsulation layer 400 may cover and protect the display element 310. The encapsulation layer 400 may include at least one inorganic encapsulation layer and at least one organic encapsulation layer. In detail, as shown in FIG. 4, the encapsulation layer 400 may include a first inorganic encapsulation layer 410, an organic encapsulation layer 420, and a second inorganic encapsulation layer 430.

The first inorganic encapsulation layer 410 may cover the opposite electrode 313 and may include silicon oxide (SiO_{X}), silicon nitride (SiN_{X}) and/or silicon oxynitride (SiO_{X}N_{Y}). As necessary, other layers, such as, a capping layer, may be interposed between the first inorganic encapsulation layer 410 and the opposite electrode 313. Because the first inorganic encapsulation layer 410 is formed along structures below the first inorganic encapsulation layer 410, the upper surface thereof may not be flat, e.g., may include steps, as shown in FIG. 4. The organic encapsulation layer 420 covers the first inorganic encapsulation layer 410. In contrast with the first inorganic encapsulation layer 410, the organic encapsulation layer 420 may have a generally flat upper surface. The organic encapsulation layer 420 may include at least one material from among polyethylene terephthalate, polyethylene naphthalate, polycarbonate, polyimide, polyethylene sulfonate, polyoxymethylene, polyarylate, or hexamethyldisiloxane. The second inorganic encapsulation layer 430 may cover the organic encapsulation layer 420, and may include silicon oxide (SiO_{X}), silicon nitride (SiN_{X}) and/or silicon oxynitride (SiO_{X}N_{Y}).

As such, the encapsulation layer 400 includes the first inorganic encapsulation layer 410, the organic encapsulation layer 420, and the second inorganic encapsulation layer 430, and thus, even when the encapsulation layer 400 cracks due to this multi-layered structure, the cracks may not be connected between the first inorganic encapsulation layer 410 and the organic encapsulation layer 420 or between the organic encapsulation layer 420 and the second inorganic encapsulation layer 430. Accordingly, formation of a path via which external moisture, oxygen, or the like permeates into the display panel 10a may be prevented or minimized.

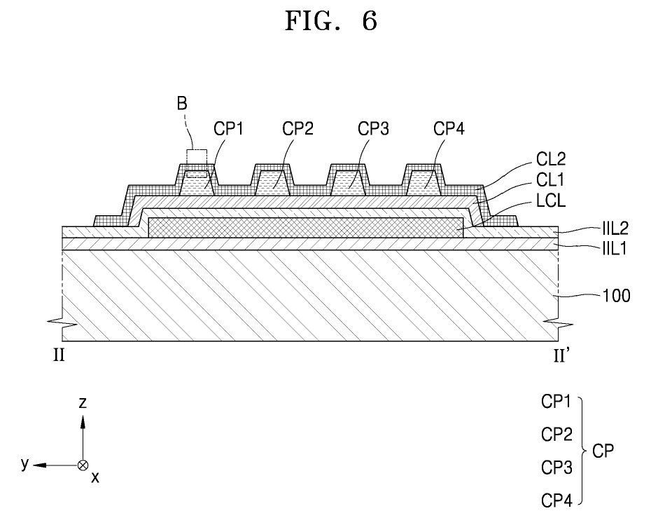

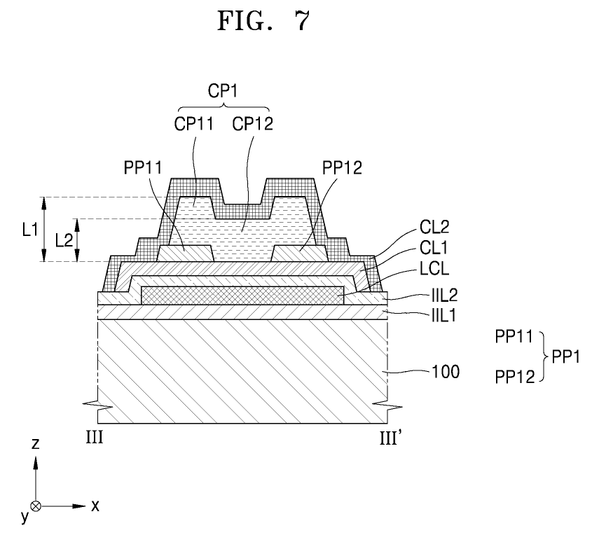

FIG. 5 is a schematic magnified plan view of a portion A of the display device of FIG. 2. However, for convenience of explanation, in FIG. 5, a first conductive layer CL1, a convex portion CP, and a protrusion PP arranged under a second conductive layer CL2 of a pad PD are depicted on the second inorganic insulating layer IIL2, and the second conductive layer CL2 of the pad PD is indicated by a dashed line. FIG. 6 is a schematic cross-sectional view of the display apparatus 10 of FIG. 5 taken along line II-II'. FIG. 7 is a schematic cross-sectional view of the display apparatus 10 of FIG. 5 taken along line III-III'.

As illustrated in FIGS. 5 and 6, a pad PD, which is an area to which the electronic chip package 10b, a printed circuit board, or the like may be electrically connected, may be disposed in the peripheral area PA. In the partial cross-sectional view shown in the example of FIG. 6, a thickness direction of the pad PD is the same as the z-axis direction. In other examples, a thickness direction of the pad may be different from the z-axis direction. The pad PD may include the first conductive layer CL1, the second conductive layer CL2, the convex portion CP, and the protrusion PP.

The pad PD may be disposed on the peripheral area PA. The first inorganic insulating layer IIL1 may be arranged on the peripheral area PA of the substrate 100, and the second inorganic insulating layer IIL2 may be arranged on the first inorganic insulating layer IIL1 which in turn is arranged on the peripheral area PA. In other words, the first inorganic insulating layer IIL1 may be arranged over the display area DA and the peripheral area PA of the substrate 100, and the second inorganic insulating layer IIL2 may be arranged on the first inorganic insulating layer IIL1 arranged over the display area DA and the peripheral area PA of the substrate 100. The pad PD may be disposed on the second inorganic insulating layer IIL2 in the peripheral area PA.

Turning to the details of the pad PD, the first conductive layer CL1 may be disposed on the second inorganic insulating layer IIL2. The first conductive layer CL1 may be formed of the same material as the source electrode SE and the drain electrode DE arranged in the display area DA by using the same process as a process for forming the source electrode SE and the drain electrode DE, and may be formed simultaneously with the source electrode SE and the drain electrode DE. Specifically, a material used to form the source electrode SE and the drain electrode DE may be deposited on the entire surface of the substrate 100. Thereafter, the material deposited on the entire surface of the substrate 100 to form the source electrode SE and the drain electrode DE may be patterned so that the source electrode SE, the drain electrode DE, and the first conductive layer CL1 may be formed. Accordingly, the source electrode SE, the drain electrode DE, and the first conductive layer CL1 may include the same material. In some examples, the first conductive layer CL1 may include a conductive material including molybdenum (Mo), aluminum (Al), copper (Cu), titanium (Ti), or the like and may have a single-layer or multi-layer structure including the aforementioned conductive material. According to an embodiment, the first conductive layer CL1 may have a multi-layer structure of Ti/Al/Ti.

The second conductive layer CL2 may be disposed on the first conductive layer CL1. The second conductive layer CL2 may cover the first conductive layer CL1. The second conductive layer CL2 may be formed of the same material as the connection electrode CE arranged in the display area DA by using the same process as a process for forming the connection electrode CE, and may be formed simultaneously with the connection electrode CE. Specifically, a material used to form the connection electrode CE may be deposited on the entire surface of the substrate 100. Thereafter, the material deposited on the entire surface of the substrate 100 to form the connection electrode CE may be patterned so that the connection electrode CE and the second conductive layer CL2 may be formed. Accordingly, the connection electrode CE and the second conductive layer CL2 may include the same material. In some examples, the second conductive layer CL2 may include a conductive material including molybdenum (Mo), aluminum (Al), copper (Cu), titanium (Ti), or the like and may have a single-layer or multi-layer structure including the aforementioned conductive material.

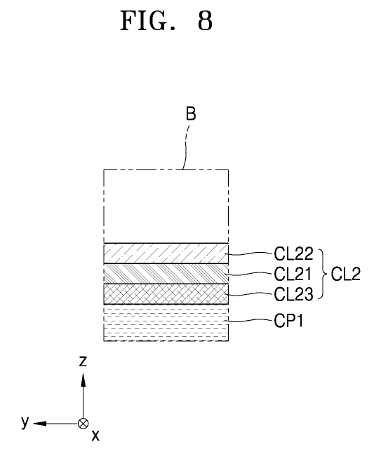

Further details of the second conductive layer CL2 are illustrated in FIG. 8, which is a cross-sectional view schematically illustrating an enlargement of a portion B of FIG. 6. As shown in FIG. 8, the second conductive layer CL2 may include a main metal layer CL21, a protective metal layer CL22, and an auxiliary metal layer CL23. The main metal layer CL21 may include a highly conductive material. For example, the main metal layer CL21 may include aluminum (Al).

The protective metal layer CL22 may be disposed on the main metal layer CL21. The protective metal layer CL22 may prevent the main metal layer CL21 from being damaged. The protective metal layer CL22 may include titanium (Ti). The auxiliary metal layer CL23 may be disposed below the main metal layer CL21. In other words, the main metal layer CL21 may be interposed between the protective metal layer CL22 and the auxiliary metal layer CL23. The auxiliary metal layer CL23 may improve an adhesive strength between the second conductive layer CL2 and a layer disposed below the second conductive layer CL2. The auxiliary metal layer CL23 may include titanium (Ti) and specific characteristics of the material may take into consideration conductivity and adhesiveness.

For example, the second conductive layer CL2 may have a multi-layer structure of Ti/Al/Ti.

The convex portion CP may be interposed between the first conductive layer CL1 and the second conductive layer CL2. That is, the convex portion CP may be disposed on the first conductive layer CL1, and the second conductive layer CL2 may be disposed on the first conductive layer CL1 and the convex portion CP. In other words, the convex portion CP may cover a portion of the first conductive layer CL1, and the second conductive layer CL2 may cover the convex portion CP and the first conductive layer CL1. Accordingly, a portion of the second conductive layer CL2 may be in direct contact with the convex portion CP, and another portion of the second conductive layer CL2 may be in direct contact with the first conductive layer CL1. The above-described characteristics of the convex portion CP demonstrate that the convex portion CP may be a buildup of material over one or more specific surface areas on the first conductive layer CL1 where the one or more specific surface areas collectively represent less than a full surface area of the first conductive layer CL1, as shown in FIGS. 6 and 7, for example.

The convex portion CP may include an organic material. The organic material may be an organic insulating material or an organic conductive material. According to an embodiment, the convex portion CP may be formed of the same material as at least one of a plurality of insulating layers arranged in the display area DA by using the same process as a process for forming the at least one of the plurality of insulating layers, and may be formed simultaneously with the at least one of the plurality of insulating layers. For example, the convex portion CP may be formed of the same material as an insulating layer interposed between the source electrode SE and the connection electrode CE arranged in the display area DA by using the same process as a process for forming the insulating layer, and may be formed simultaneously with the insulating layer.

According to an embodiment, the convex portion CP may include a plurality of sub-convex portions. Specifically, the convex portion CP may include a first convex portion CP1 and a second convex portion CP2. In FIGS. 5 and 6, the convex portion CP is illustrated as further including a third convex portion CP3 and a fourth convex portion CP4 in addition to the first convex portion CP1 and the second convex portion CP2. However, the disclosure is not limited thereto. The number of sub-convex portions may vary according to a design of the pad PD.

The first convex portion CP1 and the second convex portion CP2 may be spaced apart from each other in one direction and arranged on the first conductive layer CL1. For example, the first convex portion CP1 and the second convex portion CP2 may be arranged apart from each other in a first direction (for example, a y-axis direction).

When the convex portion CP further includes the third convex portion CP3 and the fourth convex portion CP4 in addition to the first convex portion CP1 and the second convex portion CP2, the first convex portion CP1, the second convex portion CP2, the third convex portion CP3, and the fourth convex portion CP4 may be arranged apart from each other in the first direction (e.g., the y-axis direction).

A portion of the second conductive layer CL2 that is in direct contact with the convex portion CP may be formed to be convex in a direction away from the substrate 100 compared to another portion of the second conductive layer CL2 that is in direct contact with the first conductive layer CL1, as shown in FIGS. 6 and 7, for example. That is, a portion of the pad PD may be formed convexly in the direction away from the substrate 100. Such portion of the pad PD, i.e., the portion including convex portion CP, may be in direct contact with a corresponding bump BP of the electronic chip package 10b. Accordingly, the pad PD may be electrically connected to the corresponding bump BP of the electronic chip package 10b. Because another portion of the second conductive layer CL2 separate from the portion of the second conductive layer CL2 that is in direct contact with the convex portion CP directly contacts the first conductive layer CL1, the first conductive layer CL1 and the second conductive layer CL2 may be electrically connected to each other.

As shown in FIGS. 5 and 7, the protrusion PP may be interposed between the first conductive layer CL1 and the convex portion CP. That is, the protrusion PP may be disposed on the first conductive layer CL1, and the convex portion CP may be disposed on the first conductive layer CL1 and the protrusion PP. At least a portion of the protrusion PP may overlap the convex portion CP. In other words, the protrusion PP may cover a portion of the first conductive layer CL1, and the convex portion CP may cover at least a portion of the protrusion PP and a portion of the first conductive layer CL1. Accordingly, a portion of the convex portion CP may be in direct contact with the protrusion PP, and another portion of the convex portion CP may be in direct contact with the first conductive layer CL1.

The protrusion PP may include an organic material. The organic material may be an organic insulating material or an organic conductive material. According to an embodiment, the protrusion PP may be formed of the same material as at least one of a plurality of insulating layers arranged in the display area DA by using the same process as a process for forming the at least one of the plurality of insulating layers, and may be formed simultaneously with the at least one of the plurality of insulating layers.

For example, the protrusion PP may be formed of the same material as an insulating layer interposed between the source electrode SE and the connection electrode CE arranged in the display area DA by using the same process as a process for forming the insulating layer, and may be formed simultaneously with the insulating layer.

According to an embodiment, the protrusion PP may include a plurality of sub-protrusions. In detail, the protrusion PP may include a first protrusion PP1 and a second protrusion PP2. When the convex portion CP includes the first convex portion CP1, the second convex portion CP2, the third convex portion CP3, and the fourth convex portion CP4, the protrusion PP may include the first protrusion PP1, the second protrusion PP2, a third protrusion PP3, and a fourth protrusion PP4.

The first protrusion PP1 and the second protrusion PP2 may be spaced apart from each other in one direction and arranged on the first conductive layer CL1. For example, the first protrusion PP1 and the second protrusion PP2 may be arranged apart from each other in the first direction (for example, the y-axis direction). When the protrusion PP includes the first protrusion PP1, the second protrusion PP2, the third protrusion PP3, and the fourth protrusion PP4, the first protrusion PP1, the second protrusion PP2, the third protrusion PP3, and the fourth protrusion PP4 may be arranged apart from each other in the first direction (e.g., the y-axis direction).

The first protrusion PP1, the second protrusion PP2, the third protrusion PP3, and the fourth protrusion PP4 may be interposed between the first conductive layer CL1 and the convex portion CP. Specifically, the first protrusion PP1 may be interposed between the first conductive layer CL1 and the first convex portion CP1, and the second protrusion PP2 may be interposed between the first conductive layer CL1 and the second convex portion CP2. The third protrusion PP3 may be interposed between the first conductive layer CL1 and the third convex portion CP3, and the fourth protrusion PP4 may be interposed between the first conductive layer CL1 and the fourth convex portion CP4.

The first protrusion PP1, the second protrusion PP2, the third protrusion PP3, and the fourth protrusion PP4 may at least partially overlap the convex portion CP in the thickness direction of the pad PD. Specifically, the first protrusion PP1 may at least partially overlap the first convex portion CP1 in the thickness direction, and the second protrusion PP2 may at least partially overlap the second convex portion CP2 in the thickness direction. The third protrusion PP3 may at least partially overlap the third convex portion CP3 in the thickness direction, and the fourth protrusion PP4 may at least partially overlap the fourth convex portion CP4 in the thickness direction.

In other words, the first convex portion CP1 may cover at least a portion of the first protrusion PP1 and a portion of the first conductive layer CL1, and the second convex portion CP2 may cover at least a portion of the second protrusion PP2 and a portion of the first conductive layer CL1. The third convex portion CP3 may cover at least a portion of the third protrusion PP3 and a portion of the first conductive layer CL1, and the fourth convex portion CP4 may cover at least a portion of the fourth protrusion PP4 and a portion of the first conductive layer CL1.

According to an embodiment, the first protrusion PP1 may include a 1-1 protrusion PP11 and a 1-2 protrusion PP12. These protrusions may also be referred to throughout the present disclosure as a first sub-protrusion of the protrusion PP1 and a second sub-protrusion of the protrusion PP1, respectively. Similar terminology may also be used to describe sub-protrusions of the second, third and fourth protrusions PP2, PP3, PP4, respectively, irrespective of their separate characterization as such below. The 1-1 protrusion PP11 and the 1-2 protrusion PP12 may be arranged apart from each other in a second direction (for example, an x-axis direction) intersecting, i.e., transverse to the first direction (for example, the y-axis direction). In the non-limiting arrangement depicted in FIG. 5, the 1-1 protrusion PP11 and the 1-2 protrusion PP12 are spaced apart in a second direction perpendicular to the first direction. Each of the 1-1 protrusion PP11 and the 1-2 protrusion PP12 may at least partially overlap the first convex portion CP1 in the thickness direction of the pad. In a plan view, such as that shown in FIG. 5, the 1-1 protrusion PP11 may extend along one side of the first convex portion CP1, while the 1-2 protrusion PP12 may extend along a side opposite to the one side of the first convex portion CP1. In other words, the first convex portion CP1 may cover at least a portion of the 1-1 protrusion PP11 and at least a portion of the 1-2 protrusion PP12, and the first convex portion CP1 may cover a portion of the first conductive layer CL1 between the 1-1 protrusion PP11 and the 1-2 protrusion PP12.

Accordingly, as illustrated in FIG. 7, an upper surface of the first convex portion CP1 may have a 'U' shape. That is, because the first convex portion CP1 is formed along the first protrusion PP1, which is a structure positioned below the first convex portion CP1, the upper surface of the first convex portion CP1 may be non-uniform, i.e., not flat, as illustrated in FIG. 7. In detail, the first convex portion CP1 may include a 1-1 portion CP11 that overlaps the first protrusion PP1 in the thickness direction and a 1-2 portion CP12 that does not overlap the first protrusion PP1 in the thickness direction.

That is, the 1-1 portion CP11 of the first convex portion CP1 may be in direct contact with the first protrusion PP1, and the 1-2 portion CP12 of the first convex portion CP1 may be in direct contact with the first conductive layer CL1. A length L1 between the upper surface of the 1-1 portion CP11 and the upper surface of the first conductive layer CL1 may be greater than a length L2 between the upper surface of the 1-2 portion CP12 and the upper surface of the first conductive layer CL1. 'A length between A and B' used herein refers to the shortest length between A and B in the thickness direction of a substrate (e.g., a z-axis direction). Accordingly, as illustrated in FIG. 7, the upper surface of the first convex portion CP1 may have a 'U' shape.

The above-described details regarding the shape of the upper surface of the first convex portion CP1 are also applicable to the shape of the upper surface of the second convex portion CP2, the shape of the upper surface of the third convex portion CP3, and the shape of the upper surface of the fourth convex portion CP4, so any redundant description thereof will be omitted.

For example, the second protrusion PP2 may include a 2-1 protrusion PP21 and a 2-2 protrusion PP22. For example, the 2-1 protrusion PP21 and the 2-2 protrusion PP22 may be arranged apart from each other in the second direction (for example, the x-axis direction). Each of the 2-1 protrusion PP21 and the 2-2 protrusion PP22 may at least partially overlap the second convex portion CP2 in the thickness direction. In a plan view, the 2-1 protrusion PP21 may extend along one side of the second convex portion CP2 while the 2-2 protrusion PP22 may extend along a side opposite to the one side of the second convex portion CP2. In other words, the second convex portion CP2 may cover at least a portion of the 2-1 protrusion PP21 and at least a portion of the 2-2 protrusion PP22, and the second convex portion CP2 may cover a portion of the first conductive layer CL1 between the 2-1 protrusion PP21 and the 2-2 protrusion PP22.

Accordingly, the second convex portion CP2 may include a 2-1 portion that overlaps the second protrusion PP2 in the thickness direction and a 2-2 portion that does not overlap the second protrusion PP2 in the thickness direction, and a length between the upper surface of the 2-1 portion and the upper surface of the first conductive layer CL1 may be greater than a length between the upper surface of the 2-2 portion and the upper surface of the first conductive layer CL1.

Similarly, the third protrusion PP3 may include a 3-1 protrusion PP31 and a 3-2 protrusion PP32. The 3-1 protrusion PP31 and the 3-2 protrusion PP32 may be arranged apart from each other in the second direction (for example, the x-axis direction). Each of the 3-1 protrusion PP31 and the 3-2 protrusion PP32 may at least partially overlap the third convex portion CP3 in the thickness direction.

In a plan view, the 3-1 protrusion PP31 may extend along one side of the third convex portion CP3 while the 3-2 protrusion PP32 may extend along a side opposite to the one side of the third convex portion CP3. In other words, the third convex portion CP3 may cover at least a portion of the 3-1 protrusion PP31 and at least a portion of the 3-2 protrusion PP32, and the third convex portion CP3 may cover a portion of the first conductive layer CL1 between the 3-1 protrusion PP31 and the 3-2 protrusion PP32.

The fourth protrusion PP4 may include a 4-1 protrusion PP41 and a 4-2 protrusion PP42. The 4-1 protrusion PP41 and the 4-2 protrusion PP42 may be arranged apart from each other in the second direction (for example, the x-axis direction). Each of the 4-1 protrusion PP41 and the 4-2 protrusion PP42 may at least partially overlap the fourth convex portion CP4 in the thickness direction. In a plan view, the 4-1 protrusion PP41 may extend along one side of the fourth convex portion CP4 while the 4-2 protrusion PP42 may extend along a side opposite to the one side of the fourth convex portion CP4. In other words, the fourth convex portion CP4 may cover at least a portion of the 4-1 protrusion PP41 and at least a portion of the 4-2 protrusion PP42, and the fourth convex portion CP4 may cover a portion of the first conductive layer CL1 between the 4-1 protrusion PP41 and the 4-2 protrusion PP42.

Further to the above, the third convex portion CP3 may include a 3-1 portion that overlaps the third protrusion PP3 in the thickness direction and a 3-2 portion that does not overlap the third protrusion PP3 in the thickness direction, and a length between the upper surface of the 3-1 portion and the upper surface of the first conductive layer CL1 may be greater than a length between the upper surface of the 3-2 portion and the upper surface of the first conductive layer CL1. The fourth convex portion CP4 may include a 4-1 portion that overlaps the fourth protrusion PP4 in the thickness direction and a 4-2 portion that does not overlap the fourth protrusion PP4 in the thickness direction, and a length between the upper surface of the 4-1 portion and the upper surface of the first conductive layer CL1 may be greater than a length between the upper surface of the 4-2 portion and the upper surface of the first conductive layer CL1. That is, the convex portion CP may include a first portion that overlaps the protrusion PP in the thickness direction and a second portion that does not overlap the protrusion PP in the thickness direction, and a length between the upper surface of the first portion and the upper surface of the first conductive layer CL1 may be greater than a length between the upper surface of the second portion and the upper surface of the first conductive layer CL1.

As described above, the display panel 10a for displaying an image, etc. is electrically connected to the electronic chip package 10b that provides information about the image, etc. That is, the pad PD of the display panel 10a may be electrically connected to the corresponding bump BP of the electronic chip package 10b. In some examples, when the pad PD of the display panel 10a includes the convex portion CP shaped so that a portion of the pad PD is formed convexly in the direction away from the substrate 100, a non-conductive film (NCF) may be interposed between the pad PD of the display panel 10a and the bump BP of the electronic chip package 10b, and heat and/or pressure may be applied to bond the pad PD with the bump BP in a high-temperature and high-pressure environment. Accordingly, the display panel 10a may be electrically connected to the electronic chip package 10b.

In general, when no protrusion PP is interposed between the first conductive layer CL1 and the convex portion CP, the upper surface of the convex portion CP may be flat. Accordingly, the upper surface of the pad PD, for example, the upper surface of the second conductive layer CL2, may also be flat. In such case, when the pad PD of the display panel 10a and the bump BP of the electronic chip package 10b come into direct contact, the contact area may be small. Therefore, an adhesion strength between the pad PD and the bump BP may be low, and a contact resistance between the pad PD and the bump BP may be high.

However, in the presently described embodiment, because the protrusion PP is interposed between the first conductive layer CL1 and the convex portion CP, the upper surface of the convex portion CP may be non-uniform, i.e., not flat. Accordingly, the upper surface of the pad PD, for example, the upper surface of the second conductive layer CL2, may not be flat. In this case, when the pad PD of the display panel 10a and the bump BP of the electronic chip package 10b come into direct contact, the contact area may be large relative to a pad without a protrusion. Therefore, the adhesion strength between the pad PD and the bump BP may be high. In addition, when pressure is applied to the pad PD of the display panel 10a and the bump BP of the electronic chip package 10b, a crack may occur in the protective metal layer CL22 of the second conductive layer CL2, and aluminum (Al) of the main metal layer CL21 of the second conductive layer CL2 may diffuse into the bump BP. Therefore, the contact resistance between the pad PD and the bump BP may be small. That is, the reliability of the display apparatus 10 may be increased.

In addition, in the present embodiment, because the upper surface of the second conductive layer CL2 has a 'U' shape, when pressure is applied to the pad PD of the display panel 10a and the bump BP of the electronic chip package 10b, the NCF interposed between the pad PD and the bump BP may easily move along a 'U'-shaped passage formed on the upper surface of the second conductive layer CL2.

As illustrated in FIGS. 6 and 7, a lower conductive layer LCL may be disposed under the pad PD. Specifically, the lower conductive layer LCL may be disposed under the first conductive layer CL1 of the pad PD. That is, because the pad PD is disposed on the second inorganic insulating layer IIL2, the second inorganic insulating layer IIL2 may be interposed between the first conductive layer CL1 of the pad PD and the lower conductive layer LCL. In other words, the lower conductive layer LCL may be disposed on the first inorganic insulating layer IIL1, the second inorganic insulating layer IIL2 may be disposed on the lower conductive layer LCL, and the first conductive layer CL1 may be disposed on the second inorganic insulating layer IIL2.

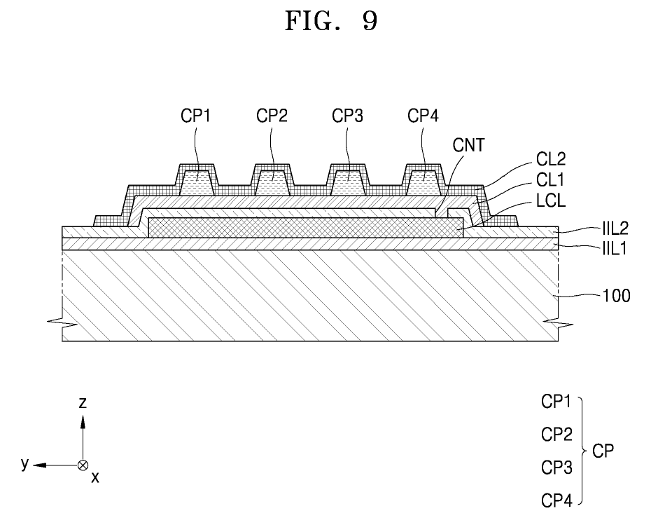

The lower conductive layer LCL may be electrically connected to the first conductive layer CL1 of the pad PD. For example, as illustrated in FIG. 9, which is a schematic cross-sectional view of the display apparatus 10 according to an embodiment, the first conductive layer CL1 may be connected to the lower conductive layer LCL through a pad contact hole CNT formed in the second inorganic insulating layer IIL2. Accordingly, the lower conductive layer LCL may be electrically connected to the first conductive layer CL1. However, the disclosure is not limited thereto. For example, the second inorganic insulating layer IIL2 may be formed to cover only an edge of the lower conductive layer LCL and the first conductive layer CL1 is formed on the lower conductive layer LCL, so that the lower conductive layer LCL may be electrically connected to the first conductive layer CL1.

The lower conductive layer LCL may be formed of the same material as the gate electrode GE arranged in the display area DA by using the same process as a process for forming the gate electrode GE, and may be formed simultaneously with the gate electrode GE. Specifically, a material used to form the gate electrode GE may be deposited on the entire surface of the substrate 100. Thereafter, the material deposited on the entire surface of the substrate 100 to form the gate electrode GE may be patterned so that the gate electrode GE and the lower conductive layer LCL may be formed. Accordingly, the gate electrode GE and the lower conductive layer LCL may include the same material. For example, the lower conductive layer LCL may include a conductive material including molybdenum (Mo), aluminum (Al), copper (Cu), titanium (Ti), or the like and may have a single-layer or multi-layer structure including the aforementioned conductive material.

Although not shown in the drawings, the lower conductive layer LCL may be electrically connected to connection wiring (not shown) arranged in the peripheral area PA. The connection wiring may electrically connect signal lines arranged in the display area DA, for example, data lines (or scan lines), to the pad PD.

In FIG. 5, the 1-1 protrusion PP11 and the 1-2 protrusion PP12 are depicted as being spaced apart from each other in the second direction (e.g., in the x-axis direction). However, the disclosure is not limited thereto. For example, the 1-1 protrusion PP11 and the 1-2 protrusion PP12 may be arranged apart from each other in the first direction (for example, the y-axis direction).

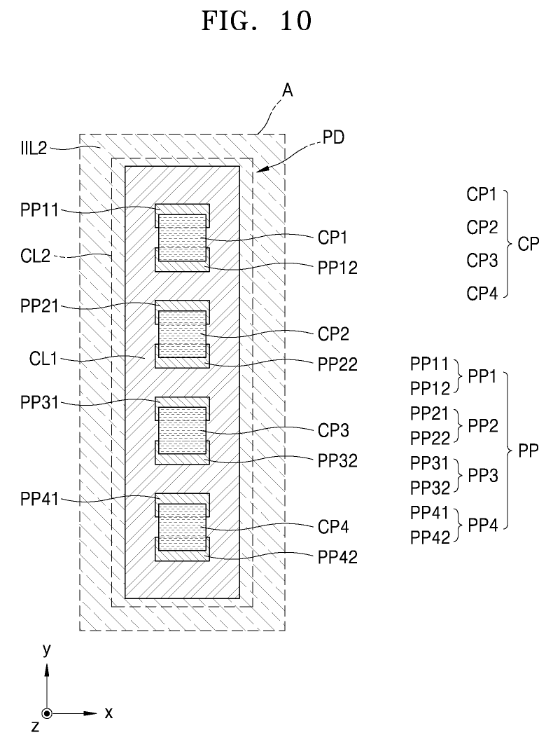

FIG. 10 is a schematic plan view of a display apparatus 10 according to an embodiment. Because the display apparatus 10 according to the present embodiment is similar to the display apparatus 10 described above with reference to FIGS. 2 through 9, a difference from the display apparatus 10 described above with reference to FIGS. 2 through 9 will now be focused on and described. Reference numerals in FIG. 10 that are the same as the reference numerals in FIGS. 2 through 9 denote the same elements, and thus repeated descriptions thereof are omitted.

The pad PD of the display apparatus 10 described above with reference to FIGS. 2 through 9 includes the first conductive layer CL1, the second conductive layer CL2, the convex portion CP, and the protrusion PP, and the protrusion PP includes the first protrusion PP1, the second protrusion PP2, the third protrusion PP3, and the fourth protrusion PP4. The first protrusion PP1 includes the 1-1 protrusion PP11 and the 1-2 protrusion PP12, the second protrusion PP2 includes the 2-1 protrusion PP21 and the 2-2 protrusion PP22, the third protrusion PP3 includes the 3-1 protrusion PP31 and the 3-2 protrusion PP32, and the fourth protrusion PP4 includes the 4-1 protrusion PP41 and the 4-2 protrusion PP42.

The pad PD of the display apparatus 10 according to the present embodiment also includes the first conductive layer CL1, the second conductive layer CL2, the convex portion CP, and the protrusion PP, and the protrusion PP includes the first protrusion PP1, the second protrusion PP2, the third protrusion PP3, and the fourth protrusion PP4. The first protrusion PP1 includes the 1-1 protrusion PP11 and the 1-2 protrusion PP12, and the second protrusion PP2 includes the 2-1 protrusion PP21 and the 2-2 protrusion PP22. The third protrusion PP3 includes the 3-1 protrusion PP31 and the 3-2 protrusion PP32, and the fourth protrusion PP4 includes the 4-1 protrusion PP41 and the 4-2 protrusion PP42.

However, as illustrated in FIG. 10, in the case of the display apparatus 10 according to the present embodiment, the 1-1 protrusion PP11 and the 1-2 protrusion PP12 may be arranged apart from each other in the first direction (e.g., in the y-axis direction), and the 2-1 protrusion PP21 and the 2-2 protrusion PP22 may be arranged apart from each other in the first direction (e.g., in the y-axis direction). The 3-1 protrusion PP31 and the 3-2 protrusion PP32 may be arranged apart from each other in the first direction (e.g., in the y-axis direction), and the 4-1 protrusion PP41 and the 4-2 protrusion PP42 may be arranged apart from each other in the first direction (e.g., in the y-axis direction).

Even in this case, the upper surface of each of the first convex portion CP1, the second convex portion CP2, the third convex portion CP3, and the fourth convex portion CP4 may have a 'U' shape. That is, the upper surface of the pad PD, for example, the upper surface of the second conductive layer CL2, may be non-uniform, i.e., not flat. Therefore, even in the case of the display apparatus 10 according to the present embodiment, an adhesion strength between the pad PD and the bump BP may be high, and a contact resistance between the pad PD and the bump BP may be small. That is, the reliability of the display apparatus 10 may be increased.

In FIGS. 5 and 10, the first protrusion PP1 and the second protrusion PP2 are depicted as being spaced apart from each other in the first direction (e.g., in the y-axis direction). However, the disclosure is not limited thereto. For example, the first protrusion PP1 and the second protrusion PP2 may be integrally provided. That is, the first protrusion PP1 and the second protrusion PP2 may be integrally formed, i.e., monolithically.

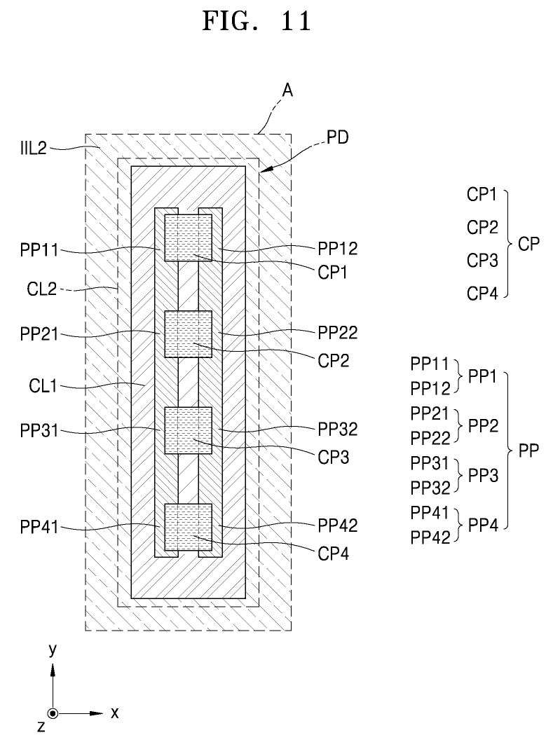

FIG. 11 is a schematic plan view of a display apparatus 10 according to an embodiment. Because the display apparatus 10 according to the present embodiment is similar to the display apparatus 10 described above with reference to FIGS. 2 through 9, a difference from the display apparatus 10 described above with reference to FIGS. 2 through 9 will now be focused on and described. Reference numerals in FIG. 11 that are the same as the reference numerals in FIGS. 2 through 9 denote the same elements, and thus repeated descriptions thereof are omitted.

In the case of the display apparatus 10 described above with reference to FIGS. 2 through 9, the 1-1 protrusion PP11 and the 1-2 protrusion PP12 of the first protrusion PP1 may be arranged apart from each other in the second direction (e.g., in the x-axis direction), the 2-1 protrusion PP21 and the 2-2 protrusion PP22 of the second protrusion PP2 may be arranged apart from each other in the second direction (e.g., in the x-axis direction), the 3-1 protrusion PP31 and the 3-2 protrusion PP32 of the third protrusion PP3 may be arranged apart from each other in the second direction (e.g., in the x-axis direction), and the 4-1 protrusion PP41 and the 4-2 protrusion PP42 of the fourth protrusion PP4 may be arranged apart from each other in the second direction (e.g., in the x-axis direction).

However, even in the case of the display apparatus 10 according to the present embodiment shown in FIG. 11, the 1-1 protrusion PP11 and the 1-2 protrusion PP12 of the first protrusion PP1 may be arranged apart from each other in the second direction (e.g., in the x-axis direction), the 2-1 protrusion PP21 and the 2-2 protrusion PP22 of the second protrusion PP2 may be arranged apart from each other in the second direction (e.g., in the x-axis direction), the 3-1 protrusion PP31 and the 3-2 protrusion PP32 of the third protrusion PP3 may be arranged apart from each other in the second direction (e.g., in the x-axis direction), and the 4-1 protrusion PP41 and the 4-2 protrusion PP42 of the fourth protrusion PP4 may be arranged apart from each other in the second direction (e.g., in the x-axis direction).

However, as illustrated in FIG. 11, in the case of the display apparatus 10 according to the present embodiment, the first protrusion PP1, the second protrusion PP2, the third protrusion PP3, and the fourth protrusion PP4 may be integrally provided. For example, the 1-1 protrusion PP11, the 2-1 protrusion PP21, the 3-1 protrusion PP31, and the 4-1 protrusion PP41 may be integrally provided, and the 1-2 protrusion PP12, the 2-2 protrusion PP22, the 3-2 protrusion PP32, and the 4-2 protrusion PP42 may be integrally provided. In some examples, the 1-1 protrusion PP11 and the 2-1 protrusion PP21 may be integrally provided, and the 1-2 protrusion PP12 and the 2-2 protrusion PP22 may be integrally provided.

Even in this case, the upper surface of each of the first convex portion CP1, the second convex portion CP2, the third convex portion CP3, and the fourth convex portion CP4 may have a 'U' shape. That is, the upper surface of the pad PD, for example, the upper surface of the second conductive layer CL2, may be non-uniform, i.e., not flat. Therefore, even in the case of the display apparatus 10 according to the present embodiment, an adhesion strength between the pad PD and the bump BP may be high, and a contact resistance between the pad PD and the bump BP may be small. That is, the reliability of the display apparatus 10 may be increased.

According to embodiments as described above, a display apparatus with improved reliability, and an electronic apparatus including the display apparatus may be realized. Of course, the scope of the disclosure is not limited to these effects.

It should be understood that embodiments described herein should be considered in a descriptive sense only and not for purposes of limitation. It should be appreciated that descriptions of features or aspects within each embodiment may be considered as available as a substitution for other similar features or aspects in other embodiments and/or as an additional feature to include in other embodiments. While one or more embodiments have been described with reference to the figures, it will be understood by those of ordinary skill in the art that various changes in form and details may be made herein without departing from the spirit and scope as defined by the following claims.

What is claimed is:

1. A display apparatus comprising:
a substrate comprising a display area and a peripheral area outside of the display area;
a display element disposed on the display area; and
a pad disposed on the peripheral area, the pad comprising:
a first conductive layer disposed on the peripheral area;
a second conductive layer disposed on the first conductive layer;
a convex portion interposed between the first conductive layer and the second conductive layer; and
a protrusion interposed between the first conductive layer and the convex portion, at least a portion of the protrusion overlapping the convex portion in a thickness direction of the pad.

2. The display apparatus of claim 1, wherein
a first portion of the convex portion is in direct contact with the first conductive layer, and
a second portion of the convex portion is in direct contact with the protrusion.

3. The display apparatus of claim 1, wherein the convex portion is a first convex portion and the display apparatus further comprises a second convex portion that is arranged apart from the first convex portion along a first direction.

4. The display apparatus of claim 3, wherein
the protrusion is a first protrusion and the display apparatus further comprises a second protrusion that is arranged apart from the first protrusion along the first direction,
the first protrusion being interposed between the first conductive layer and the first convex portion, at least a portion of the first protrusion overlapping the first convex portion in the thickness direction, and
the second protrusion being interposed between the first conductive layer and the second convex portion, at least a portion of the second protrusion overlapping the second convex portion in the thickness direction.

5. The display apparatus of claim 4, wherein
the first protrusion includes a first sub-protrusion and a second sub-protrusion that are arranged apart from each other along a second direction, the second direction being transverse to the first direction, and
each of the first sub-protrusion and the second sub-protrusion at least partially overlaps the first convex portion in the thickness direction.

6. The display apparatus of claim 5, wherein,
in a plane perpendicular to the thickness direction, the first sub-protrusion extends along a first side of the first convex portion and the second sub-protrusion extends along a second side of the first convex portion opposite to the first side of the first convex portion.

7. The display apparatus of claim 5, wherein
the second protrusion includes a first sub-protrusion and a second sub-protrusion that are arranged apart from each other along the second direction, and
each of the first sub-protrusion of the second protrusion and the second sub-protrusion of the second protrusion at least partially overlaps the second convex portion in the thickness direction.

8. The display apparatus of claim 7, wherein,
in a plane perpendicular to the thickness direction, the first sub-protrusion of the second protrusion extends along a first side of the second convex portion and the second sub-protrusion of the second protrusion extends along a second side of the second convex portion opposite to the first side of the second convex portion.

9. The display apparatus of claim 7, wherein
the first sub-protrusion of the first protrusion and the first sub-protrusion of the second protrusion are integrally formed, and
the second sub-protrusion of the first protrusion and the second sub-protrusion of the second protrusion are integrally formed.

10. The display apparatus of claim 4, wherein
the first protrusion includes a first sub-protrusion and a second sub-protrusion that are arranged apart from each other along the first direction, and
each of the first sub-protrusion and the second sub-protrusion at least partially overlaps the first convex portion in the thickness direction.

11. The display apparatus of claim 10, wherein
the second protrusion includes a first sub-protrusion and a second sub-protrusion that are arranged apart from each other along the first direction, and
each of the first sub-protrusion of the second protrusion and the second sub-protrusion of the second protrusion at least partially overlaps the second convex portion in the thickness direction.

12. The display apparatus of claim 1, wherein the second conductive layer covers the convex portion and the first conductive layer.

13. The display apparatus of claim 12, wherein
a first portion of the second conductive layer is in direct contact with the convex portion, and
a second portion of the second conductive layer is in direct contact with the first conductive layer.

14. The display apparatus of claim 1, wherein
the convex portion includes a first portion that overlaps the protrusion in the thickness direction and a second portion that does not overlap the protrusion in the thickness direction, and
a length between an upper surface of the first portion and an upper surface of the first conductive layer in the thickness direction is greater than a length between an upper surface of the second portion and the upper surface of the first conductive layer in the thickness direction.

15. The display apparatus of claim 1, further comprising a lower conductive layer disposed below the first conductive layer such that the first conductive layer is in between the lower conductive layer and the second conductive layer, the lower conductive layer being electrically connected to the first conductive layer.

16. An electronic apparatus comprising:
a processor; and
a display apparatus controlled by the processor, the display apparatus comprising:
a substrate comprising a display area and a peripheral area outside the display area;
a display element disposed on the display area; and
a pad disposed on the peripheral area,
the pad comprising:
a first conductive layer disposed on the peripheral area;
a second conductive layer disposed on the first conductive layer;
a convex portion interposed between the first conductive layer and the second conductive layer; and
a protrusion interposed between the first conductive layer and the convex portion, at least a portion of the protrusion overlapping the convex portion in a thickness direction of the pad.

17. The electronic apparatus of claim 16, wherein
a first portion of the convex portion is in direct contact with the first conductive layer, and
a second portion of the convex portion is in direct contact with the protrusion.

18. The electronic apparatus of claim 16, wherein
the convex portion is a first convex portion and the electronic apparatus further comprises a second convex portion that is arranged apart from the first convex portion along a first direction,
the protrusion is a first protrusion and the electronic apparatus further comprises a second protrusion that is arranged apart from the first protrusion along the first direction,
the first protrusion being interposed between the first conductive layer and the first convex portion, at least a portion of the first protrusion overlapping the first convex portion in the thickness direction, and
the second protrusion being interposed between the first conductive layer and the second convex portion, at least a portion of the second protrusion overlapping the second convex portion in the thickness direction.

19. The electronic apparatus of claim 16, wherein
the convex portion includes a first portion that overlaps the protrusion in the thickness direction and a second portion that does not overlap the protrusion in the thickness direction, and
a length between an upper surface of the first portion and an upper surface of the first conductive layer in the thickness direction is greater than a length between an upper surface of the second portion and the upper surface of the first conductive layer in the thickness direction.

20. The electronic apparatus of claim 16, wherein the display apparatus further comprises a lower conductive layer disposed below the first conductive layer such that the first conductive layer is in between the lower conductive layer and the second conductive layer, the lower conductive layer being electrically connected to the first conductive layer.
